(19) United States
(12) Patent Application Publication
(10) Pub. No.: US 2025/0279392 A1
(43) Pub. Date: Sep. 4, 2025

(54) METHOD FOR PRODUCING SEMICONDUCTOR DEVICE, AND SEMICONDUCTOR DEVICE

(71) Applicant: Resonac Corporation, Minato-ku, Tokyo (JP)

(72) Inventors: Shizu FUKUZUMI, Minato-ku, Tokyo (JP); Keiko UENO, Minato-ku, Tokyo (JP)

(21) Appl. No.: 18/857,185

(22) PCT Filed: Apr. 22, 2022
(86) PCT No.: PCT/JP2022/018581

§ 371 Date: Oct. 16, 2024

(51) Int. Cl. H01L 23/00; H01L 21/56; H01L 25/00; H01L 25/065

(52) U.S. Cl. CPC H01L 24/80; H01L 21/56; H01L 24/08; H01L 24/16; H01L 24/29; H01L 24/32; H01L 24/73; H01L 24/81; H01L 24/83; H01L 24/92; H01L 25/0657; H01L 25/50; H01L 2224/08145; H01L 2224/16145; H01L 2224/16227; H01L 2224/2979; H01L 2224/32145; H01L 2224/32225; H01L 2224/73204; H01L 2224/80203; H01L 2224/80895; H01L 2224/80896; H01L 2224/81191; H01L 2224/83104; H01L 2224/83862; H01L 2224/83874; H01L 2224/92125; H01L 2225/06513; H01L 2225/06517; H01L 2225/06524; H01L 2225/06565; H01L 2924/3701

(57) ABSTRACT

A method for producing a semiconductor device includes preparing a first semiconductor substrate having a first substrate body, a first insulating layer, and a plurality of first electrodes, preparing a second semiconductor substrate having a second substrate body, a second insulating layer, and a plurality of second electrodes, bonding the first insulating layer and the second insulating layer to each other while joining the plurality of first electrodes to the plurality of second electrodes to obtain a hybrid bonding structure, forming a plurality of connection bumps on the second substrate body, dicing the hybrid bonding structure to obtain a plurality of hybrid bonding structure components, mounting the first hybrid bonding structure component on another member, injecting a first liquid material into a gap between the first hybrid bonding structure component and the other member, and curing the first liquid material.

### TECHNICAL FIELD

The present disclosure relates to a method for producing a semiconductor device, and a semiconductor device.

### BACKGROUND ART

Conventionally, a wire bonding method using a metal thin wire such as a gold wire has been widely applied to connect a semiconductor chip to a substrate. On the other hand, a flip chip (FC) connection method of forming a conductive protrusion called a bump on a semiconductor chip or a substrate to directly connect the semiconductor chip to the substrate is becoming widespread to meet a demand for higher functionality, higher integration, higher speed, and the like of a semiconductor device.

As the FC connection method, a method of metal-bonding a connection portion using solder, tin, gold, silver, copper, or the like, a method of metal-bonding a connection portion by applying ultrasonic vibration, a method of maintaining mechanical contact by contraction force of resin, and the like are known. From the viewpoint of reliability of the connection portion, the method of metal-bonding the connection portion using solder, tin, gold, silver, copper, or the like is common.

For example, regarding connection between a semiconductor chip and a substrate, a chip on board (COB) type connection method actively used for a ball grid array (BGA), a chip size package (CSP), and the like also corresponds to the FC connection method. The FC connection method is also widely used in a chip on chip (COC) type connection method in which a connection portion (bump or wiring) is formed on a semiconductor chip to connect the semiconductor chips to each other (refer to, for example, Patent Literature 1.).

In addition, in packages that are strongly required to be further downsized, thinned, and highly functional, chip stack-type packages in which the above-described connection methods are stacked in multiple stages, package on package (POP), through-silicon via (TSV), and the like have also started to be widely used. In such a stacking or multi-stage stacking technique, since the semiconductor chips and the like are three-dimensionally arranged, the package can be made smaller than that using a technique in which the chips are two-dimensionally arranged. In addition, such a stacking or multi-stage stacking technique is also effective for improving performance of a semiconductor, reducing noise, reducing a mounting area, and saving power, and thus has attracted attention as a next-generation semiconductor wiring technique.

### CITATION LIST

### Patent Literature

Patent Literature 1: Japanese Unexamined Patent Publication No. 2012-222038

### SUMMARY OF INVENTION

### Technical Problem

As described in Patent Literature 1, when a semiconductor device is produced by stacking a large number of semiconductor chips by flip chip connection, the height of each connection bump is accumulated and thus the semiconductor device becomes thick. In particular, when the semiconductor chips are stacked in multiple stages, the influence of the height of the connection bump on the thickness of the semiconductor device cannot be ignored. Thus, a production method capable of reducing the height of the semiconductor device is desired.

An object of the present disclosure is to provide a method for producing a semiconductor device, and a semiconductor device capable of reducing the height of the semiconductor device.

### Solution to Problem

As one aspect, the present disclosure relates to a method for producing a semiconductor device. The method for producing the semiconductor device includes: preparing a first semiconductor substrate including a first substrate body, a first insulating layer, and a plurality of first electrodes, the first substrate body including a plurality of first semiconductor elements, the first insulating layer and the plurality of first electrodes being provided on the first substrate body; preparing a second semiconductor substrate including a second substrate body, a second insulating layer, and a plurality of second electrodes, the second substrate body including a plurality of second semiconductor elements, the second insulating layer and the plurality of second electrodes being provided on the second substrate body; bonding the first insulating layer of the first semiconductor substrate and the second insulating layer of the second semiconductor substrate to each other and joining the plurality of first electrodes of the first semiconductor substrate to the plurality of second electrodes of the second semiconductor substrate to obtain a hybrid bonding structure; forming a plurality of connection bumps on a surface of the second substrate body opposite to the second insulating layer; dicing the hybrid bonding structure in which the plurality of connection bumps are formed to obtain a plurality of hybrid bonding structure components each including at least one first semiconductor element, at least one first electrode, at least one second semiconductor element, at least one second electrode, and at least one connection bump; mounting a first hybrid bonding structure component among the plurality of hybrid bonding structure components on another member; injecting a curable first liquid material into a gap between the first hybrid bonding structure component and the other member; and curing the first liquid material.

In the above method for producing the semiconductor device, the first hybrid bonding structure is fabricated using the hybrid bonding technique that bonds and connects semiconductor chips (or semiconductor wafers or the like) to each other without using a connection bump, the connection bump is formed on the first hybrid bonding structure, and the first hybrid bonding structure is diced to obtain the plurality of hybrid bonding structure components. Then, mounting is performed using such a first hybrid bonding structure component with the connection bump, and the first liquid material is injected into the gap with another component on which the first hybrid bonding structure component is mounted, and the first liquid material is cured. According to such a production method, the hybrid bonding technique is used to connect some of the semiconductor chips, and thus the thickness and the height of the semiconductor device can be reduced, as compared with the case where all the semiconductor chips are connected by the connection bumps. In addition, in the conventional production method, the production process is long because the semiconductor chips are stacked and connected by flip-chip connection at each stage; however, according to the above-described method for producing the semiconductor device, it is possible to collectively connect some of the semiconductor chips using the hybrid bonding technique, thus making it possible to shorten the production process and improve productivity.

The method for producing the semiconductor device preferably further includes: mounting a second hybrid bonding structure component among the plurality of hybrid bonding structure components on the first hybrid bonding structure component; injecting a curable second liquid material into a gap between the second hybrid bonding structure component and the first hybrid bonding structure component; and curing the second liquid material. According to the production method, it is possible to reduce the height of the semiconductor device even when the semiconductor chips are stacked in multiple stages. In addition, the production process of the semiconductor device can be shortened to improve productivity.

In the above-described method for producing the semiconductor device, the injecting of the first liquid material and the injecting of the second liquid material may be separately performed. According to the production method, the injection of the first liquid material and the injection of the second liquid material can be performed more reliably, thus making it possible to easily fabricate a highly reliable semiconductor device.

The above-described method for producing the semiconductor device may further include encapsulating the first hybrid bonding structure component and the second hybrid bonding structure component, and the injecting of the first liquid material and the injecting of the second liquid material may be performed in this encapsulating. According to the production method, an encapsulating material is used not only to encapsulate the first hybrid bonding structure component and the second hybrid bonding, but also as an underfill material, and thus it is possible to collectively perform the encapsulating of the hybrid bonding structure components and the protection of the connection bumps. Therefore, according to the production method, the productivity of the semiconductor device can be further improved.

In the above-described method for producing the semiconductor device, the other member may be a substrate having a wiring electrode provided on the surface, and in the mounting of the first hybrid bonding structure component, the first hybrid bonding structure component may be mounted on the substrate such that the connection bump of the first hybrid bonding structure component is connected to the wiring electrode. According to the production method, it is possible to reduce the height of the semiconductor device in which the semiconductor chip is mounted on the substrate.

In the above-described method for producing the semiconductor device, at least one of the first insulating layer of the first semiconductor substrate and the second insulating layer of the second semiconductor substrate may include an inorganic insulating material. According to the production method, it is possible to fabricate a semiconductor device having a finer configuration. In addition, since the joining between inorganic materials is easily strengthened, it is possible to increase the adhesive strength between the semiconductor chips, and further improve the connection reliability as the semiconductor device.

In the above-described method for producing the semiconductor device, at least one of the first insulating layer of the first semiconductor substrate and the second insulating layer of the second semiconductor substrate may include an organic insulating material. According to the production method, the organic material, which is a relatively soft material, absorbs (incorporates) debris generated when the semiconductor substrate is diced into the semiconductor chip in the insulating layer portion made of the organic material, thus making it possible to reduce connection failure between the semiconductor chips joined by hybrid bonding.

In the above-described method for producing the semiconductor device, the organic insulating material included in at least one of the first insulating layer and the second insulating layer may contain polyimide, a polyimide precursor, polyamideimide, benzocyclobutene (BCB), polybenzoxazole (PBO), or a PBO precursor. In this case, since these materials are liquid or soluble in a solvent, the first insulating layer and the like can be easily fabricated by, for example, spin coating, making it easier to form a thin film. In addition, since these materials are highly heat resistant, they can withstand high temperatures and the like when joining is performed by hybrid bonding, thus making it possible to perform joining between the semiconductor chips more reliably.

In the above-described method for producing the semiconductor device, the first liquid material may be a liquid epoxy resin composition containing at least an epoxy resin and a curing agent.

As another aspect, the present disclosure relates to a semiconductor device. The semiconductor device includes a first hybrid bonding structure component, another member, and a cured object of a first liquid material. The first hybrid bonding structure component includes a first semiconductor component, a second semiconductor component, and a first connection bump. The first semiconductor component includes a first semiconductor chip, a first insulating layer, and a first electrode. The first insulating layer and the first electrode are provided on the first semiconductor chip. The second semiconductor component includes a second semiconductor chip, a second insulating layer, and a second electrode. The second insulating layer and the second electrode are provided on a first surface of the second semiconductor chip. The first connection bump is provided on a second surface of the second semiconductor chip and connected to an electrode of the second semiconductor chip. The first insulating layer and the second insulating layer are bonded to each other, while the first electrode is joined to the second electrode. Another member mounts the first hybrid bonding structure component thereon. The cured object of the first liquid material is injected between the first hybrid bonding structure component and the other member so as to cover the first connection bump, to be cured.

In the above semiconductor device, the first hybrid bonding structure component using the hybrid bonding technique that bonds and connects the semiconductor chips (or the semiconductor wafers or the like) to each other without using a connection bump is used. Therefore, it is possible to reduce the thickness and the height of the semiconductor device, as compared with a semiconductor device in which all the semiconductor chips are connected by the connection bumps.

The above-described semiconductor device may further include a second hybrid bonding structure component mounted on the first hybrid bonding structure component. The second hybrid bonding structure component includes a third semiconductor component, a fourth semiconductor component, and a second connection bump. The third semiconductor component includes a third semiconductor chip, a third insulating layer, and a third electrode. The third insulating layer and the third electrode are provided on the third semiconductor chip. The fourth semiconductor component includes a fourth semiconductor chip, a fourth insulating layer, and a fourth electrode. The fourth insulating layer and the fourth electrode are provided on a first surface of the fourth semiconductor chip. The second connection bump is provided on a second surface of the fourth semiconductor chip and connected to the electrode of the fourth semiconductor chip. The third insulating layer and the fourth insulating layer are bonded to each other, while the third electrode is joined to the fourth electrode. The cured object of the second liquid material is injected between the second hybrid bonding structure component and the first hybrid bonding structure component so as to cover the second connection bump, to be cured. According to the semiconductor device, it is possible to reduce the height of the semiconductor device even when the semiconductor chips are stacked in multiple stages.

In the above-described semiconductor device, the other member may be a substrate having a wiring electrode, and the first connection bump may be connected to the wiring electrode. According to the semiconductor device, it is possible to reduce the height of the semiconductor device in which the semiconductor chip is mounted on the substrate.

In the above-described semiconductor device, at least one of the first insulating layer and the second insulating layer may include an inorganic insulating material. According to this configuration, it is possible to fabricate a semiconductor device having a finer configuration. In addition, since the joining between inorganic materials is easily strengthened, it is possible to increase the adhesive strength between the semiconductor chips, and further improve the connection reliability as the semiconductor device.

In the above-described semiconductor device, at least one of the first insulating layer and the second insulating layer may include an organic insulating material. According to this configuration, the organic material, which is a relatively soft material, absorbs (incorporates) debris generated during dicing into the semiconductor chip in the insulating layer portion made of the organic material, thus making it possible to reduce connection failure between the semiconductor chips joined by hybrid bonding.

In the above-described semiconductor device, the cured object of the first liquid material may be a cured object of a liquid epoxy resin composition containing at least an epoxy resin and a curing agent.

### Advantageous Effects of Invention

According to the present disclosure, the height of the semiconductor device can be reduced.

### BRIEF DESCRIPTION OF DRAWINGS

FIG. 1 is a cross-sectional view schematically illustrating a semiconductor device according to an embodiment of the present disclosure.

FIGS. 2A and 2B are cross-sectional views sequentially illustrating a method for producing the semiconductor device illustrated in FIG. 1.

FIG. 3 is a cross-sectional view sequentially illustrating the method for producing the semiconductor device illustrated in FIG. 1, and is a view illustrating a step following the steps illustrated in FIGS. 2A and 2B.

FIGS. 4A and 4B are cross-sectional views sequentially illustrating the method for producing the semiconductor device illustrated in FIG. 1, and are views illustrating a step following the step illustrated in FIG. 3.

FIGS. 5A and 5B are cross-sectional views sequentially illustrating the method for producing the semiconductor device illustrated in FIG. 1, and are views illustrating a step following the steps illustrated in FIGS. 4A and 4B.

FIGS. 6A and 6B are cross-sectional views sequentially illustrating the method for producing the semiconductor device illustrated in FIG. 1, and are views illustrating a step following the steps illustrated in FIGS. 5A and 5B.

FIGS. 7A and 7B are cross-sectional views illustrating another example of the method for producing the semiconductor device illustrated in FIG. 1.

### DESCRIPTION OF EMBODIMENTS

Hereinafter, some embodiments of the present disclosure will be described in detail with reference to the drawings as necessary. In the following description, the same or corresponding portions are denoted by the same reference numerals, and redundant description is omitted. Unless otherwise specified, the positional relationship such as upper, lower, left, and right sides is based on the positional relationship illustrated in the drawings. The use of the terms “left,” “right,” “front,” “back,” “upper,” “lower,” “above,” “below,” and the like in the description and the claims is intended for description and does not necessarily mean a permanent relative position. The dimensional ratios in the drawings are not limited to the illustrated ratios.

The term “layer” herein includes a structure in which a shape is partially formed in addition to a structure in which a shape is formed on the entire surface when observed as a plan view. The term “step” herein includes not only an independent step but also a step that cannot be clearly distinguished from other steps as long as an intended action of the step is achieved. A numerical range expressed using “to” indicates a range including numerical values described before and after “to” as a minimum value and a maximum value, respectively.

### Configuration of Semiconductor Device

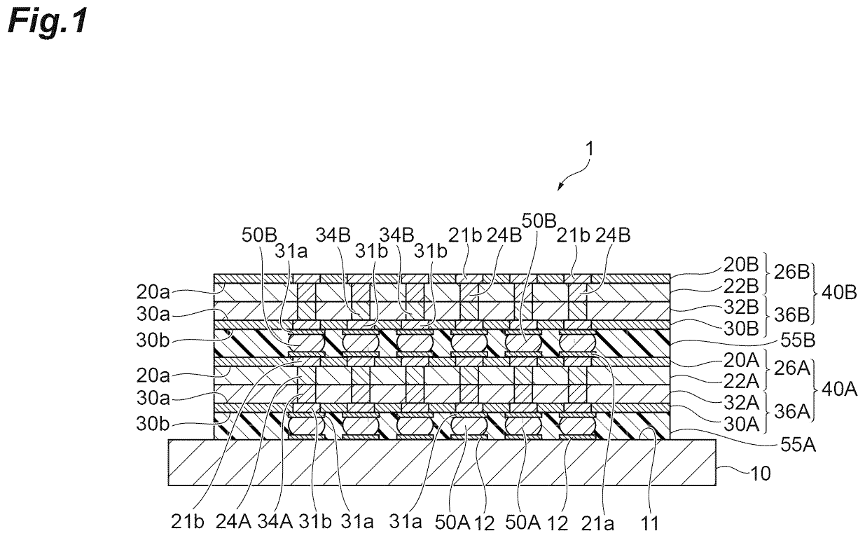

FIG. 1 is a cross-sectional view schematically illustrating one example of a semiconductor device according to the present embodiment. As illustrated in FIG. 1, a semiconductor device 1 is an example of a semiconductor package, for example, and includes a substrate 10, a set of a first hybrid bonding structure component 40A and a first connector 55A arranged on the substrate 10, and another set of a second hybrid bonding structure component 40B and a second connector 55B further arranged on the first hybrid bonding structure component 40A. In the semiconductor device 1, the first connector 55A, the first hybrid bonding structure component 40A, the second connector 55B, and the second hybrid bonding structure component 40B are sequentially stacked on the substrate 10.

The substrate 10 has a plurality of wiring electrodes 12 on a front surface 11. The substrate 10 is not particularly limited as long as it is a wiring circuit board, and the following circuit boards can be used: a circuit board in which wiring (a wiring pattern) is formed by etching and removing unnecessary portions of a metal layer formed on the surface of an insulating substrate mainly composed of glass epoxy, polyimide, polyester, ceramic, epoxy, bismaleimide triazine, polyimide, or the like, a circuit board in which wiring (a wiring pattern) is formed on the surface of the insulating substrate by metal plating or the like, a circuit board in which wiring (a wiring pattern) is formed on the surface of the insulating substrate by printing a conductive substance, or the like. The wiring electrode 12 includes, for example, gold, silver, and copper.

The first hybrid bonding structure component 40A includes a first semiconductor component 26A including a first semiconductor chip 20A, and a first insulating layer 22A and a plurality of first electrodes 24A that are provided on the first semiconductor chip 20A, a second semiconductor component 36A including a second semiconductor chip 30A, and a second insulating layer 32A and a plurality of second electrodes 34A that are provided on a first surface 30a of the second semiconductor chip 30A, and a first connection bump 50A provided on a second surface 30b of the second semiconductor chip 30A and connected to a terminal electrode 31a of the second semiconductor chip 30A. The first hybrid bonding structure component 40A arranged on the substrate 10 is attached to the substrate 10 by the first connection bump 50A. More specifically, the terminal electrode 31a of the first hybrid bonding structure component 40A is connected to the wiring electrode 12 of the substrate 10 by the first connection bump 50A. A cured object of an adhesive liquid resin composition (a first liquid material) constituting the first connector 55A is filled around the first connection bump 50A.

In the first hybrid bonding structure component 40A, the first insulating layer 22A and the second insulating layer 32A are bonded to each other, while the plurality of first electrodes 24A are joined to the plurality of second electrodes 34. The first electrode 24A is electrically connected to wiring constituted by a semiconductor element included in the first semiconductor chip 20A. The second electrode 34A is electrically connected to wiring constituted by a semiconductor element included in the second semiconductor chip 30A. Note that various conventional methods can be used for a method for forming the plurality of first electrodes 24A in the first insulating layer 22A and a method for forming the plurality of second electrodes 34A in the second insulating layer 32A, and thus detailed description is omitted here.

The first semiconductor chip 20A and the second semiconductor chip 30A are not particularly limited, and can use various semiconductors such as an element semiconductor composed of one type of element such as silicon or germanium, and a compound semiconductor such as gallium arsenide and indium phosphide. The first semiconductor chip 20A and the second semiconductor chip 30A may have terminal electrodes 21a and 31a for connecting the semiconductor chip to the outside, and through electrodes 21b and 31b penetrating the semiconductor chip. The terminal electrode 21a of the first semiconductor chip 20A is connected to a terminal electrode 31a of a fourth semiconductor chip 30B via a second connection bump 50B described later. The through electrode 21b of the first semiconductor chip 20A is connected to the terminal electrode 21a and the first electrode 24A. The terminal electrode 31a of the second semiconductor chip 30A is connected to the wiring electrode 12 of the substrate 10 via the first connection bump 50A. The through electrode 31b of the second semiconductor chip 30A is connected to the terminal electrode 31a and the second electrode 34A. The thicknesses of the first semiconductor chip 20A and the second semiconductor chip 30A are, for example, in the range of 0.2 mm to 2.0 mm.

The first insulating layer 22A and the second insulating layer 32A include an inorganic insulating material or an organic insulating material. The first insulating layer 22A and the second insulating layer 32A may include both the inorganic insulating material and the organic insulating material. The inorganic insulating material used for the insulating layer is, for example, silicon oxide (SiO₂) or the like. When the inorganic insulating material such as silicon oxide is used for the insulating layer, a semiconductor device having a finer configuration can be fabricated. Since the joining between inorganic insulating materials is easily strengthened, it is possible to increase the adhesive strength between the semiconductor chips, and improve the connection reliability as the semiconductor device.

The organic insulating material used for the first insulating layer 22A and the second insulating layer 32A is, for example, polyimide, a polyimide precursor (for example, a polyimide amic ester or a polyamic acid), polyamideimide, benzocyclobutene (BCB), polybenzoxazole (PBO), or a PBO precursor. These organic insulating materials have a lower elastic modulus than, for example, inorganic insulating materials such as silicon oxide (SiO₂), and are soft materials. By using such organic insulating materials, even if there is fine debris on the insulating layer when the insulating layers are bonded to each other, the debris is absorbed into the insulating layer to prevent bonding failure due to the debris, thus making it possible to reliably bond the insulating layers to each other. The elastic modulus of the organic material constituting the first insulating layer 22A and the second insulating layer 32A may be, for example, 7.0 GPa or less, 5.0 GPa or less, 3.0 GPa or less, 2.0 GPa or less, or 1.5 GPa or less. The elastic modulus here means Young's modulus. The organic insulating material constituting the first insulating layer 22A and the second insulating layer 32A preferably has a thermal expansion coefficient of 70 ppm/K or less, and more preferably 50 ppm/K or less.

The thicknesses of the first insulating layer 22A and the second insulating layer 32A are preferably 10 μm or less, more preferably 5 μm or less, and still more preferably 3 μm or less. By setting the thicknesses of the first insulating layer 22A and the second insulating layer 32A to such thicknesses, the first electrode 24A and the second electrode 34A formed in the first insulating layer 22A and the second insulating layer 32A can be miniaturized, thus making it possible to reduce the thickness of the semiconductor device 1. The thicknesses of the first insulating layer 22A and the second insulating layer 32A are preferably 1 μm or more from the viewpoint of securing electrical reliability.

The first electrode 24A and the second electrode 34A are terminal electrodes provided on the inner surfaces 20a and 30a of the first semiconductor chip 20A and the second semiconductor chip 30A, and are made of, for example, copper or aluminum. The first electrode 24A penetrates the first insulating layer 22A and is exposed on a surface of the first insulating layer 22A opposite to the surface 20a to which the first semiconductor chip 20A is connected. The second electrode 34A penetrates the second insulating layer 32A and is exposed on a surface of the second insulating layer 32A opposite to the surface 30a to which the second semiconductor chip 30A is connected. In the first hybrid bonding structure component 40A, the first electrode 24A is joined to the second electrode 34A.

The first connection bump 50A is a connection member provided on the surface 30b of the second semiconductor chip 30A and connected to the terminal electrode 31a of the second semiconductor chip 30A. The first connection bump 50A contains, as a main component, gold, silver, copper, solder (whose main component is, for example, tin-silver, tin-lead, tin-bismuth, or tin-copper), nickel, tin, lead, or the like, and may contain a plurality of metals. The first connection bump 50A is connected to the wiring electrode 12 of the substrate 10 at the other end.

The first connector 55A positioned between the substrate 10 and the first hybrid bonding structure component 40A is a cured object obtained by curing a liquid adhesive resin composition, and covers the first connection bump 50A. The liquid adhesive resin composition used to form the first connector 55A is, for example, an adhesive resin composition containing an epoxy resin and a curing agent. The curing agent is, for example, an amine curing agent. The liquid resin composition used to form the first connector 55A may contain an inorganic filler, a curing accelerator, rubber particles, or the like.

The second hybrid bonding structure component 40B is arranged on the first hybrid bonding structure component 40A. The second hybrid bonding structure component 40B is attached to the first semiconductor chip 20A by the second connection bump 50B. The second hybrid bonding structure component 40B has the same configuration as that of the first hybrid bonding structure component 40A, and redundant portions may be partially omitted in the following description.

The second hybrid bonding structure component 40B includes a third semiconductor component 26B including a third semiconductor chip 20B, and a third insulating layer 22B and a plurality of third electrodes 24B that are provided on the third semiconductor chip 20B, a fourth semiconductor component 36B including the fourth semiconductor chip 30B, and a fourth insulating layer 32B and a plurality of fourth electrodes 34B that are provided on a first surface 30a of the fourth semiconductor chip 30B, and the second connection bump 50B provided on a second surface 30b of the fourth semiconductor chip 30B and connected to the terminal electrode 31a of the fourth semiconductor chip 30B. The second hybrid bonding structure component 40B arranged on the first hybrid bonding structure component 40A is attached to the first hybrid bonding structure component 40A by the second connection bump 50B. More specifically, a terminal electrode 31a of the second hybrid bonding structure component 40B is connected to the terminal electrode 21a of the first hybrid bonding structure component 40A by the second connection bump 50B. A cured object of an adhesive resin composition (a second liquid material) constituting the second connector 55B is filled around the second connection bump 50B. In the second hybrid bonding structure component 40B, the third insulating layer 22B and the fourth insulating layer 32B are bonded to each other, while the plurality of third electrodes 24B and the plurality of fourth electrodes 34B are joined to each other.

The third semiconductor chip 20B and the fourth semiconductor chip 30B are the same semiconductor chip as the first semiconductor chip 20A and the second semiconductor chip 30A, respectively. The third semiconductor chip 20B and the fourth semiconductor chip 30B may have the terminal electrodes 21a and 31a for connecting the semiconductor chip to the outside, and the through electrodes 21b and 31b penetrating the semiconductor chip. The terminal electrode 31a of the fourth semiconductor chip 30B is connected to the terminal electrode 21a of the first semiconductor chip 20A via a second connection bump 54B. The through electrode 31b of the fourth semiconductor chip 30B is connected to the terminal electrode 31a and the fourth electrode 34B. The thicknesses of the third semiconductor chip 20B and the fourth semiconductor chip 30B are, for example, in the range of 0.2 mm to 2.0 mm, similarly to the first semiconductor chip 20A.

The third insulating layer 22B and the fourth insulating layer 32B include an inorganic insulating material or an organic insulating material, similarly to the first insulating layer 22A and the second insulating layer 32A. The third insulating layer 22B and the fourth insulating layer 32B may include both the inorganic insulating material and the organic insulating material. The inorganic insulating material or the organic insulating material used for the insulating layer is the same as that of the first insulating layer 22A. Note that the thicknesses of the third insulating layer 22B and the fourth insulating layer 32B are also preferably 10 μm or less, more preferably 5 μm or less, and still more preferably 3 μm or less. The thicknesses of the third insulating layer 22B and the fourth insulating layer 32B are preferably 1 μm or more from the viewpoint of securing electrical reliability.

The third electrode 24B and the fourth electrode 34B are terminal electrodes provided on the inner surfaces 20a and 30a of the third semiconductor chip 20B and the fourth semiconductor chip 30B, and are made of, for example, copper or aluminum. The third electrode 24B penetrates the third insulating layer 22B and is exposed on a surface of the third insulating layer 22B opposite to the surface 20a to which the third semiconductor chip 20B is connected. The fourth electrode 34B penetrates the fourth insulating layer 32B and is exposed on a surface of the fourth insulating layer 32B opposite to the surface 30a to which the fourth semiconductor chip 30B is connected. In the second hybrid bonding structure component 40B, the third electrode 24B and the fourth electrode 34B are joined to each other.

The second connection bump 50B is a connection member provided on the surface 30b of the fourth semiconductor chip 30B and connected to the terminal electrode 31a of the fourth semiconductor chip 30B. Similarly to the first connection bump 50A, the second connection bump 50B contains, as a main component, gold, silver, copper, solder (whose main component is, for example, tin-silver, tin-lead, tin-bismuth, or tin-copper), nickel, tin, lead, or the like, and may contain a plurality of metals. The second connection bump 50B is connected to the terminal electrode 21a of the first semiconductor chip 20A at the other end. The second connector 55B positioned between the first hybrid bonding structure component 40A and the second hybrid bonding structure component 40B is a cured object obtained by curing a liquid adhesive resin composition, and covers the second connection bump 50B, similarly to the first connector 55A.

Here, referring to FIG. 1 again, a connection configuration in the semiconductor device 1 having the above-described configuration will be described. In the semiconductor device 1, the first hybrid bonding structure component 40A is arranged on the substrate 10, and the wiring electrode 12 of the substrate 10 is connected to the terminal electrode 31a of the second semiconductor chip 30A via the first connection bump 50A. The terminal electrode 31a is connected to the terminal electrode 21a of the first semiconductor chip 20A via the second electrode 34A, the first electrode 24A, and the through electrode 21b of the first semiconductor chip 20A. The second hybrid bonding structure component 40B is further arranged on the first hybrid bonding structure component 40A, and the terminal electrode 21a of the first semiconductor chip 20A is connected to the terminal electrode 31a of the fourth semiconductor chip 30B via the second connection bump 50B. The terminal electrode 31a is connected to the through electrode 21b of the third semiconductor chip 20B via the fourth electrode 34B and the third electrode 24B. Note that, in such a semiconductor device 1, a hybrid bonding structure component having the same configuration may be further stacked and the hybrid bonding structure components may be connected by a connection bump.

### Method for Producing Semiconductor Device

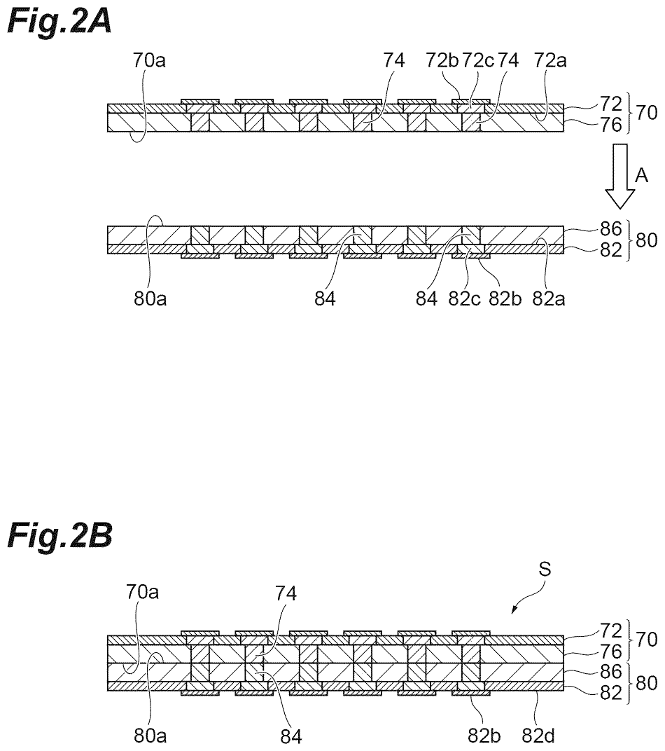

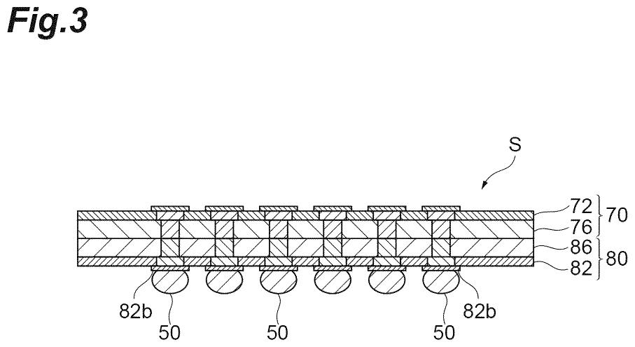

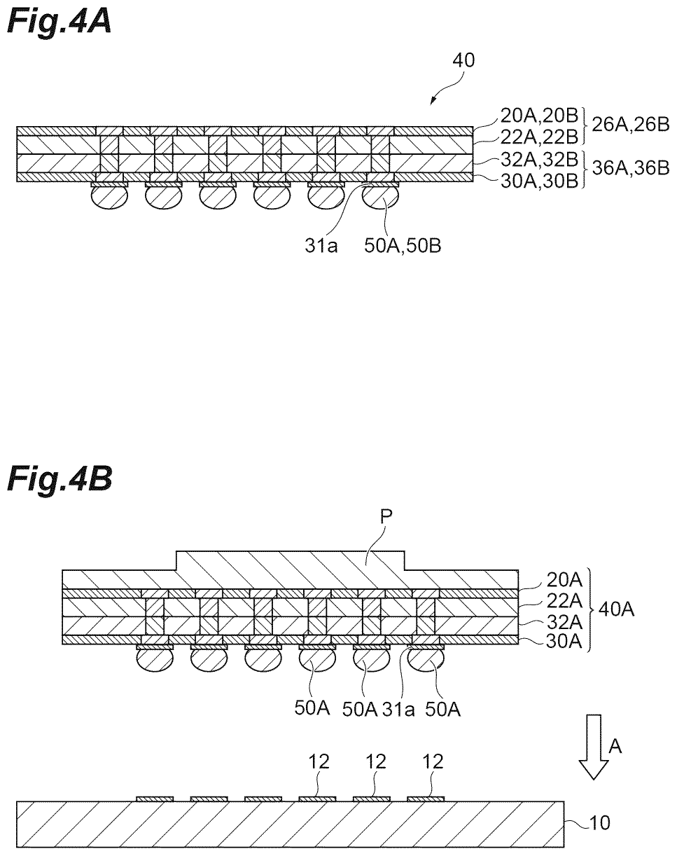

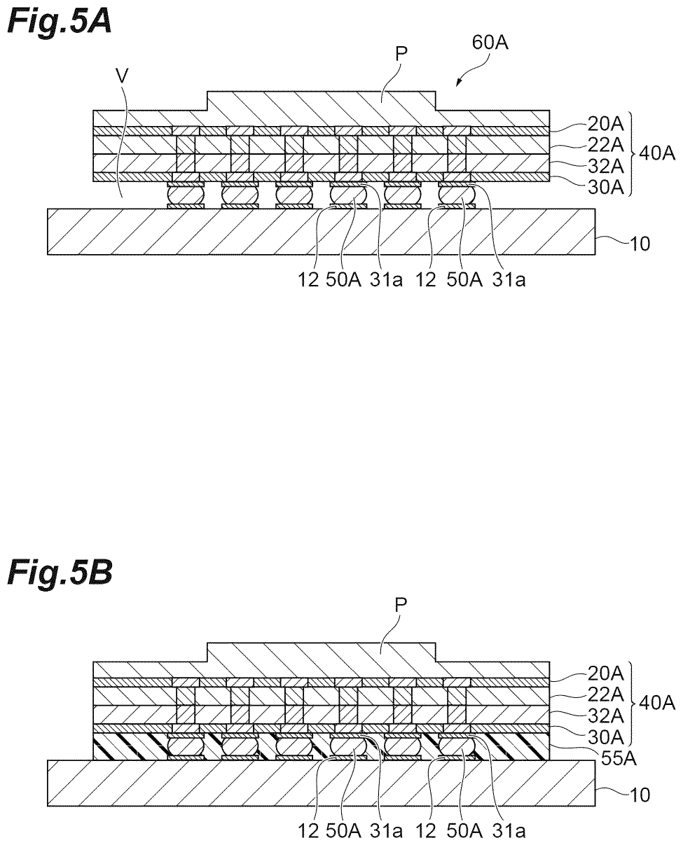

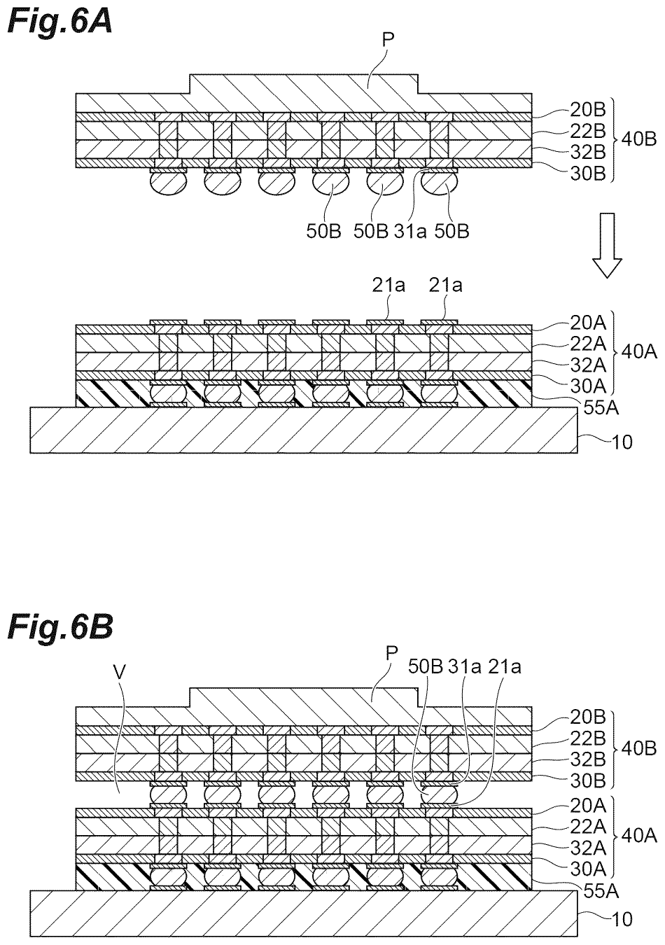

Next, a method for producing the semiconductor device 1 will be described with reference to FIGS. 2A and 2B to FIGS. 6A to 6B. FIGS. 2A and 2B are cross-sectional views sequentially illustrating the method for producing the semiconductor device illustrated in FIG. 1. FIG. 3 is a cross-sectional view sequentially illustrating the method for producing the semiconductor device illustrated in FIG. 1, and is a view illustrating a step following the steps illustrated in FIGS. 2A and 2B. FIGS. 4A and 4B are cross-sectional views sequentially illustrating the method for producing the semiconductor device illustrated in FIG. 1, and are views illustrating a step following the step illustrated in FIG. 3. FIGS. 5A and 5B are cross-sectional views sequentially illustrating the method for producing the semiconductor device illustrated in FIG. 1, and are views illustrating a step following the steps illustrated in FIGS. 4A and 4B. FIGS. 6A and 6B are cross-sectional views sequentially illustrating the method for producing the semiconductor device illustrated in FIG. 1, and are views illustrating a step following the steps illustrated in FIGS. 5A and 5B.

The semiconductor device 1 can be produced, for example, through at least the following steps (a) to (h).
(a) A step of preparing a first semiconductor substrate including a first substrate body including a plurality of first semiconductor elements, and the first insulating layer and the plurality of first electrodes that are provided on the first substrate body.
(b) A step of preparing a second semiconductor substrate including a second substrate body including a plurality of second semiconductor elements, and the second insulating layer and the plurality of second electrodes that are provided on the second substrate body.
(c) A step of bonding the first insulating layer of the first semiconductor substrate and the second insulating layer of the second semiconductor substrate to each other, while joining the plurality of first electrodes of the first semiconductor substrate to the plurality of second electrodes of the second semiconductor substrate to obtain the hybrid bonding structure.
(d) A step of forming a plurality of connection bumps on a surface of the second substrate body opposite to the second insulating layer.
(e) A step of dicing the hybrid bonding structure in which the plurality of connection bumps are formed to obtain the plurality of hybrid bonding structure components each including at least one first semiconductor element, at least one first electrode, at least one second semiconductor element, at least one second electrode, and at least one connection bump.
(f) A step of mounting the first hybrid bonding structure component among the plurality of hybrid bonding structure components on another member.
(g) A step of injecting the curable first liquid material into a gap between the first hybrid bonding structure component and the other member.
(h) A step of curing the first liquid material.
   [Step (a) and Step (b)]
   The step (a) is a step of preparing a first semiconductor substrate 70 that corresponds to a plurality of semiconductor components including the first semiconductor component 26A and the third semiconductor component 26B and is a silicon substrate on which an integrated circuit including semiconductor elements and wiring connecting the semiconductor elements is formed. In the step (a), as illustrated in FIG. 2A, a plurality of first electrodes 74 made of copper, aluminum, or the like are provided at predetermined intervals on one surface 72a of a first substrate body 72 made of silicon or the like, while a first insulating layer 76 made of an inorganic material or an organic material is provided. The first substrate body 72 may be, for example, a circular or rectangular semiconductor wafer. The first electrode 74 is an end electrode for exposing the integrated circuit or the like formed in the first semiconductor substrate 70 to the outside through the first insulating layer 76. The plurality of first electrodes 74 may be provided after the first insulating layer 76 is provided on the one surface 72a of the first substrate body 72, or the first insulating layer 76 may be provided after the plurality of first electrodes 74 are provided on the one surface 72a of the first substrate body 72. The first substrate body 72 may be provided with a terminal electrode 72b connected to the integrated circuit or the like and a through electrode 72c penetrating the substrate body.

The step (b) is a step of preparing a second semiconductor substrate 80 that corresponds to a plurality of semiconductor components including the second semiconductor component 36A and the fourth semiconductor component 36B and is a silicon substrate on which an integrated circuit including semiconductor elements and wiring connecting the semiconductor elements is formed. In the step (b), as illustrated in FIG. 2A, a plurality of second electrodes 84 made of copper, aluminum, or the like are provided at predetermined intervals on one surface 82a of a second substrate body 82 made of silicon or the like, while a second insulating layer 86 made of an inorganic material or an organic material is provided. Similarly to the first substrate body 72, the second substrate body 82 may be, for example, a circular or rectangular semiconductor wafer. The second electrode 84 is an end electrode for exposing the integrated circuit or the like formed in the second semiconductor substrate 80 to the outside through the second insulating layer 86. The plurality of second electrodes 84 may be provided after the second insulating layer 86 is provided on the one surface 82a of the second substrate body 82, or the second insulating layer 86 may be provided after the plurality of second electrodes 84 are provided on the one surface 82a of the second substrate body 82. The second substrate body 82 may be provided with a terminal electrode 82b connected to the integrated circuit or the like and a through electrode 82c penetrating the substrate body. Note that FIG. 2A illustrates only a part of the first semiconductor substrate 70 and the second semiconductor substrate 80 in the plane direction, and omits the other parts having the same configuration. The same applies to FIG. 2B and FIG. 3.

The first insulating layer 76 and the second insulating layer 86 used in the step (a) and the step (b) correspond to the first insulating layer 22A, the second insulating layer 32A, the third insulating layer 22B, and the fourth insulating layer 32B of the semiconductor device 1 described above, and include an inorganic material or an organic material. The inorganic material used for the insulating layer is, for example, silicon oxide (SiO₂) or the like. When the inorganic material such as silicon oxide is used for the insulating layer, a semiconductor device having a finer configuration can be fabricated. When the insulating layers are bonded to each other in step (c) to be described later, the joining between the inorganic materials is easily strengthened, and thus it is possible to increase the adhesive strength between the semiconductor substrates and improve the connection reliability as the semiconductor device.

The organic material used for the insulating layer is, for example, polyimide, a polyimide precursor (for example, a polyimide amic ester or a polyamic acid), polyamideimide, benzocyclobutene (BCB), polybenzoxazole (PBO), or a PBO precursor. These organic materials have a lower elastic modulus than, for example, inorganic materials such as silicon oxide (SiO₂), and are soft materials. By using such organic materials, even if there is fine debris on the insulating layer when the insulating layers are bonded to each other in the step (c) to be described later, the debris is absorbed into the insulating layer to prevent bonding failure due to the debris, thus making it possible to reliably bond the insulating layers to each other. The elastic modulus of the organic material constituting the first insulating layer 76 and the second insulating layer 86 may be, for example, 7.0 GPa or less, 5.0 GPa or less, 3.0 GPa or less, 2.0 GPa or less, or 1.5 GPa or less. The elastic modulus here means Young's modulus. The organic material constituting the first insulating layer 76 and the second insulating layer 86 preferably has a thermal expansion coefficient of 70 ppm/K or less, and more preferably 50 ppm/K or less.

Since the organic material used for the insulating layer is liquid or soluble in a solvent, each insulating layer can be easily formed as a thin film by spin coating or the like. Since these organic materials have heat resistance, they can withstand temperatures at which the first electrode 74 and the second electrode 84 are joined in the step (c) to be described later (for example, a high temperature of 300° C. or higher), thus preventing the joint between the insulating layers from being deteriorated due to the high temperature. Note that the first insulating layer 76 and the second insulating layer 86 may be an insulating layer that includes both the inorganic insulating material and the organic insulating material.

The thicknesses of the first insulating layer 76 and the second insulating layer 86 may be 20 μm or less. By sufficiently reducing the thicknesses of the first insulating layer 76 and the second insulating layer 86, the wiring and the like formed by the first electrode 74 and the second electrode 84 can have a finer configuration. Note that the thicknesses of the first insulating layer 76 and the second insulating layer 86 may be 20 μm or more. In this case, when the insulating layers are bonded to each other, more debris can be embedded in the resin insulating layer, and the insulating layers can be joined to each other more reliably. The thicknesses of the first insulating layer 76 and the second insulating layer 86 may be 4 μm or more. In this case, by embedding fine debris in the resin insulating layer, it is possible to improve connection between the first insulating layer 76 and the second insulating layer 86 even if minute debris remains.

The step (c) is a step of bonding the first insulating layer 76 of the first semiconductor substrate 70 and the second insulating layer 86 of the second semiconductor substrate 80 to each other, while joining the plurality of first electrodes 74 of the first semiconductor substrate 70 to the plurality of second electrodes 84 of the second semiconductor substrate 80 to obtain a hybrid bonding structure S. Before the step (c), as pretreatment, a bonding surface 70a of the first semiconductor substrate 70 and a bonding surface 80a of the second semiconductor substrate 80 are polished using a chemical mechanical polishing (CMP) method. The first semiconductor substrate 70 may be polished using the CMP method under the condition of selectively deeply cutting the first electrode 74 made of, for example, copper or the like, or may be polished using the CMP method such that each surface of the first electrode 74 coincides with the surface of the first insulating layer 76. The same applies to the polishing of the second semiconductor substrate 80. By such polishing, debris on the surfaces of the first semiconductor substrate 70 and the second semiconductor substrate 80 is also removed.

In the step (c), after the organic substance or the metal oxide adhering to the surfaces of the bonding surface 70a of the first semiconductor substrate 70 and the bonding surface 80a of the second semiconductor substrate 80 is removed, as illustrated in FIGS. 2A and 2B, the bonding surface 70a of the first semiconductor substrate 70 and the bonding surface 80a of the second semiconductor substrate 80 are faced to each other, and the first electrodes 74 of the first semiconductor substrate 70 and the second electrodes 84 are aligned with each other. In this alignment step, the first insulating layer 76 of the first semiconductor substrate 70 and the second insulating layer 86 of the second semiconductor substrate 80 are separated from each other and are not joined. When the alignment is completed, the first insulating layer 76 of the first semiconductor substrate 70 and the second insulating layer 86 of the second semiconductor substrate 80 are joined. At this time, the first insulating layer 76 and the second insulating layer 86 are uniformly heated before the joining. The heating temperature during the joining of the first insulating layer 76 and the second insulating layer 86 may be, for example, 30° C. or more and 400° C. or less, and the pressure may be 0.1 MPa or more and 1 MPa or less. By thermal joining at such a temperature, the first insulating layer 76 and the second insulating layer 86 are joined to form an insulating joint portion, and the first semiconductor substrate 70 and the second semiconductor substrate 80 are mechanically firmly attached to each other.

When the joining of the insulating layers is completed, the first electrodes 74 of the first semiconductor substrate 70 and the second electrodes 84 of the second semiconductor substrate 80 are joined by applying predetermined heat or pressure or both. When the first electrodes 74 and the second electrodes 84 are made of copper, the heating temperature is 150° C. or more and 400° C. or less, and may be 200° C. or more and 300°° C. or less, and the pressure may be 0.1 MPa or more and 1 MPa or less. By such a joining process, the first electrode 74 and the second electrode 84 corresponding thereto are joined to form an electrode joint portion, and the first electrode 74 and the second electrode 84 are mechanically and electrically firmly joined. Note that the electrode joining may be performed after the bonding of the insulating layers, but the electrode joining and the bonding of the insulating layers may be simultaneously performed. Thus, the hybrid bonding structure S is obtained.

In the step (d), as illustrated in FIG. 3, a plurality of connection bumps 50 are formed on a surface 82d of the second substrate body 82 of the hybrid bonding structure S opposite to the second insulating layer 86. The connection bump 50 contains, as a main component, gold, silver, copper, solder (whose main component is, for example, tin-silver, tin-lead, tin-bismuth, or tin-copper), nickel, tin, lead, or the like, and may contain a plurality of metals. In the step (d), such connection bumps 50 are formed so as to be connected to the plurality of terminal electrodes 82b of the second substrate body 82. A conventional method can be used to produce the bumps.

In the step (e), the hybrid bonding structure S in which the connection bumps 50 are provided is diced into a plurality of pieces to obtain a plurality of hybrid bonding structure components 40 each including at least one first semiconductor element, at least one first electrode 74, at least one second semiconductor element, at least one second electrode 84, and at least one connection bump 50. In the step (e), the hybrid bonding structure S is diced into pieces using plasma dicing, stealth dicing, laser dicing, or the like. As a result, as illustrated in FIG. 4A, an individual hybrid bonding structure component 40 is obtained. The hybrid bonding structure component 40 corresponds to the first hybrid bonding structure component 40A and the second hybrid bonding structure component 40B described above.

In the step (f), the first hybrid bonding structure component 40A among the plurality of hybrid bonding structure components 40 obtained by dicing is mounted on the substrate 10 that is the other member. In the step (f), first, as illustrated in FIG. 4B, the first hybrid bonding structure component 40A is picked up by a bonding tool P and moved toward the substrate 10. Thereafter, the first hybrid bonding structure component 40A is placed on the substrate 10, and then the first hybrid bonding structure component 40A is pressed while being heated. At this time, as illustrated in FIG. 5A, each of the first connection bumps 50A is connected to the corresponding wiring electrode 12. In other words, the terminal electrode 31a of the second semiconductor chip 30A is connected to the wiring electrode 12 via the first connection bump 50A. At this time, a region other than the first connection bump 50A between the first hybrid bonding structure component 40A and the substrate 10 is a gap V.

In the step (g), as illustrated in FIG. 5B, the first liquid material made of a curable resin composition is injected into the gap V between the first hybrid bonding structure component 40A and the substrate 10 by a syringe or the like. In the step (h), the injected first liquid material is cured by heat or ultraviolet ray (or light). Such a first liquid material protects the first connection bump 50A while protecting the connection between the first hybrid bonding structure component 40A and the substrate 10.

Such a first liquid material may be a capillary underfill (CUF), which is a type of semiconductor encapsulating material, and is, for example, a liquid epoxy resin composition containing an epoxy resin and a curing agent. The curing agent contained in the first liquid material is, for example, an amine curing agent. The first liquid material may contain an inorganic filler. The average particle size of the inorganic filler may be in the range of 0.3 to 5 μm.

The epoxy resin used in the first liquid material is not particularly limited, and examples thereof include a glycidyl ether type epoxy resin obtained by a reaction of bisphenol A, bisphenol F, bisphenol AD, bisphenol S, naphthalenediol, hydrogenated bisphenol A or the like with epichlorohydrin, an epoxidized novolak resin obtained by condensing or co-condensing phenols and aldehydes including an orthocresol novolak type epoxy resin, a glycidyl ester type epoxy resin obtained by a reaction of epichlorohydrin with a polybasic acid such as phthalic acid and dimer acid, an aminoglycidyl ether type epoxy resin obtained by a reaction of epichlorohydrin with a polyamine such as diaminodiphenylmethane and isocyanuric acid, a linear aliphatic epoxy resin obtained by oxidizing an olefin bond with a peracid such as peracetic acid, and an alicyclic epoxy resin.

The epoxy resin used in the first liquid material preferably contains, in particular, at least one liquid epoxy resin selected from a bisphenol A type epoxy resin, a bisphenol F type epoxy resin, a bisphenol AD type epoxy resin, a bisphenol S type epoxy resin, a naphthalenediol type epoxy resin, a hydrogenated bisphenol A type epoxy resin, and an aminoglycidyl ether type epoxy resin, and more preferably uses at least one of the liquid bisphenol F type epoxy resin and the aminoglycidyl ether type epoxy resin. Note that these may be used alone or in combination of two or more.

A reactive diluent having an epoxy group may be mixed to adjust the viscosity. Examples of the reactive diluent having an epoxy group include n-butyl glycidyl ether, versatic acid glycidyl ether, styrene oxide, ethylhexyl glycidyl ether, phenyl glycidyl ether, butyl phenyl glycidyl ether, 1,6-hexanediol diglycidyl ether, neopentyl glycol diglycidyl ether, diethylene glycol diglycidyl ether, and trimethylolpropane triglycidyl ether, and these may be used alone or in combination of two or more. These epoxy resins are preferably sufficiently purified and contain less ionic impurities. For example, free Na ions or free Cl ions are preferably 500 ppm or less.

The curing agent used in the first liquid material is not particularly limited, and examples thereof include an acid anhydride, a phenol resin, an aromatic amine, and various imidazole derivatives that are generally used as a curing agent for epoxy resins. From the viewpoint of reducing the viscosity, it is preferable to use the acid anhydride. From the viewpoint of storage stability, it is preferable to use a phenol resin and an imidazole derivative. From the viewpoint of moisture-resistant adhesion, it is preferable to use the aromatic amine. Among these compounds, it is particularly preferable to contain at least one compound selected from a liquid acid anhydride, a liquid phenol resin, and a liquid aromatic amine as the curing agent, and it is more preferable to contain the liquid aromatic amine as the curing agent. Note that, when the composition is liquid, a solid compound may be used as the curing agent, or liquid and solid compounds may be used in combination.

Examples of the acid anhydride include phthalic anhydride, tetrahydrophthalic anhydride, 3-methyltetrahydrophthalic anhydride, hymic anhydride, succinic anhydride, trimellitic anhydride, and pyromellitic anhydride, and these may be used alone or in combination of two or more.

The phenol resin is not particularly limited as long as it has two or more phenolic hydroxyl groups in the molecule, and examples thereof include a novolak-type phenol resin obtained by condensing or co-condensing phenols such as phenol, cresol, resorcin, catechol, bisphenol A, bisphenol F, phenylphenol, and aminophenol and/or naphthols such as a-naphthol, β-naphthol, and dihydroxynaphthalene with a compound having an aldehyde group such as formaldehyde under an acidic catalyst, and a phenol-aralkyl resin and a naphthol-aralkyl resin synthesized from a phenol and/or a naphthol such as allylated bisphenol A, allylated bisphenol F, allylated naphthalenediol, phenol novolak, and phenol, and dimethoxyparaxylene or bis (methoxymethyl) biphenyl, and these may be used alone or in combination of two or more.

Examples of the aromatic amine include Epicure W and Epicure Z (both are the names of products manufactured by Japan Epoxy Resins Co., Ltd.), Kayahard A-A, Kayahard A-B, and Kayahard A-S (all are the names of products manufactured by Nippon Kayaku Co., Ltd.), Tohto Amine HM-205 (name of a product manufactured by Tohto Kasei Co., Ltd.), Adeka Hardner EH-101 (name of a product manufactured by Asahi Denka Co., Ltd.), Epomik Q-640 and Epomik Q-643 (all are the names of products manufactured by Mitsui Chemicals, Inc.), and DETDA80 (name of a product manufactured by Lonza), and these may be used alone or in combination of two or more.

Examples of the imidazole derivative include 2-methylimidazole, 2-undecylimidazole, 2-heptadecylimidazole, 1,2-dimethylimidazole, 2-ethyl-4 methylimidazole, 2-phenylimidazole, 2-phenyl-4 methylimidazole, 1-benzyl-2 methylimidazole, 1-cyanoethyl-2 methylimidazole, 1-cyanoethyl-2 methylimidazole, 1-cyanoethyl-2 undecylimidazole, 1-cyanoethyl-2 phenylimidazole, 1-cyanoethyl-2 ethyl-4 methylimidazolium trimellitate, 1-cyanoethyl-2 undecylimidazolium trimellitate, 1-cyanoethyl-2 phenylimidazolium trimellitate, 2,4-diamino-6-[2′-methylimidazolyl-(1′)]-ethyl-s triazine, 2,4-diamino-6-(2′-undecylimidazolyl)-ethyl-s-triazine, 2,4-diamino-6-[2′-ethyl-4-methylimidazolyl-(1′)]-ethyl-s-triazine, 2,4-diamino-6-[2′-methylimidazolyl-(1′)]-ethyl-s-triazine isocyanuric acid adduct, 2-phenylimidazole isocyanuric acid adduct, 2-methylimidazole isocyanuric acid adduct, 2-phenyl-4,5-dihydroxydimethylimidazole, 2-phenyl-4-methyl-5-hydroxymethylimidazole, 1-cyanoethyl-2-phenyl-4,5-di (2-cyanoethoxy) methylimidazole, and these may be used in combination of two or more.

The equivalent ratio between the epoxy resin and the curing agent of the first liquid material is not particularly limited, but in order to reduce each unreacted component, the curing agent is preferably set in the range of 0.6 to 1.6 equivalents with respect to the epoxy resin, more preferably 0.7 to 1.4 equivalents, and still more preferably 0.8 to 1.2 equivalents. If the ratio is out of the range of 0.6 to 1.6, unreacted components tend to increase, deteriorating the reliability. Here, the equivalent of the phenol resin is calculated by assuming that one phenolic hydroxyl group reacts with one epoxy group, the equivalent of the aromatic amine is calculated by assuming that one active hydrogen of an amino group reacts with one epoxy group, and the equivalent of the acid anhydride is calculated by assuming that one acid anhydride group reacts with one epoxy group. Since the imidazole derivative acts as a polymerization catalyst for the epoxy resin, the blending amount thereof is determined in consideration of the curing speed and pot life of the composition.

The inorganic filler may be contained in the first liquid material. The inorganic filler is blended for the purposes including reducing the thermal expansion and imparting the rigidity and thermal conductivity of the epoxy resin composition, and usually, molten silica, crystalline silica, alumina, silicon nitride, boron nitride, silicon carbide, and the like can be used. By containing the inorganic filler, the viscosity of the liquid epoxy resin composition can be adjusted. As the inorganic filler, for example, spherical molten silica can be used. For the spherical molten silica, it is preferable to use substantially spherical molten silica produced by heating natural or synthetic silica using a thermal spraying method or the like. Here, the term “substantially spherical” means the following. That is, when the natural or synthetic silica is heated to be spheroidized, particles that have not been completely melted may not have a perfect spherical shape. A fused matter of a plurality of melted particles may be mixed. Furthermore, the evaporated silica vapor may adhere to the surfaces of other particles and solidify, resulting in spherical silica particles to which fine particles adhere. The term “substantially spherical” allows the mixture of particles having such shapes, but for example, particles with the sphericity of a particle represented by Waddle sphericity [(Diameter of a circle equal to the projected area of a particle)/(Diameter of the smallest circle circumscribing the projected image of the particle)] of 0.9 or more preferably account for 90 wt % or more of the entire inorganic filler. The average particle size of the inorganic filler used in the liquid epoxy resin composition is preferably in the range of 0.3 μm to 5 μm.

The resin composition of the first liquid material can contain the curing accelerator as necessary. The resin composition of the first liquid material can contain a coupling agent, a flexibilizer, a colorant, and the like.

The curing accelerator is not particularly limited as long as it is an accelerator generally used in epoxy resin compositions that accelerates a curing reaction between the epoxy resin and the curing agent, and various amine-based compounds, imidazole-based compounds such as 2-ethyl-4-methylimidazole, organophosphine-based compounds, quaternary ammonium, phosphonium-based compounds, and the like can be used.

Examples thereof include: cycloamidine compounds such as 1,8-diazabicyclo [5.4.0] undecene-7, 1,5-diazabicyclo [4.3.0] nonene-5, 5,6-dibutylamino-1,8-diazabicyclo [5.4.0] undecene-7, and compounds having intramolecular polarization obtained by adding compounds having a π bond such as maleic anhydride, quinone compounds such as 1,4-benzoquinone, 2,5-toluquinone, 1,4-naphthoquinone, 2,3-dimethylbenzoquinone, 2,6-dimethylbenzoquinone, 2,3-dimethoxy-5 methyl-1,4-benzoquinone, 2,3-dimethoxy-1,4-benzoquinone, and phenyl-1,4-benzoquinone, diazophenylmethane, and phenol resin to the above-described cycloamidine compounds; tertiary amines such as benzyldimethylamine, triethanolamine, dimethylaminoethanol, tris (dimethylaminomethyl) phenol, and derivatives thereof; imidazoles such as 2-methylimidazole, 2-phenylimidazole, 2-phenyl-4-methylimidazole, and 2-heptadecylimidazole, and derivatives thereof; phosphine compounds such as organic phosphines such as tributylphosphine, methyldiphenylphosphine, triphenylphosphine, tris (4-methylphenyl) phosphine, diphenylphosphine, and phenylphosphine, and phosphorus compounds having intramolecular polarization obtained by adding compounds having a π bond such as the above-described quinone compounds, maleic anhydride, diazophenylmethane, and phenol resin to the above-described phosphine compounds; and tetraphenylboron salts such as tetra-substituted phosphonium tetra-substituted borates such as tetraphenylphosphonium tetraphenylborate, tetraphenylphosphonium ethyltriphenylborate, and tetrabutylphosphonium tetrabutylborate, 2-ethyl-4-methylimidazole tetraphenylborate, and N-methylmorpholine tetraphenylborate, and derivatives thereof. These may be used alone or in combination of two or more.

The coupling agent has an effect of improving the wetting of the inorganic filler and the resin and the adhesion to an adherend, and specifically, the following can be used: γ-(2-aminoethyl) aminopropyltrimethoxysilane, γ-(2-aminoethyl) aminopropyldimethoxysilane, γ-glycidoxypropyltrimethoxysilane, γ-mercaptopropyltrimethoxysilane, γ-anilinopropyltrimethoxysilane, γ-ureidotrimethoxysilane, γ-dibutylaminopropyltrimethoxysilane, imidazolesilane, and the like. For the flexibilizer, silicones and polyolefin-based elastomers or powders thereof can be used. For the colorant, carbon black, organic dyes, organic pigments, titanium oxide, red lead, red iron oxide, and like can be used.

Subsequently, when the curable first liquid material injected into the gap V between the first hybrid bonding structure component 40A and the substrate 10 in the step (g) is cured in the step (h) and the first connector 55A is formed as illustrated in FIG. 5B, the second hybrid bonding structure component 40B is picked up by the bonding tool P, and the second hybrid bonding structure component 40B is placed on the first hybrid bonding structure component 40A and pressed while being heated, as illustrated in FIGS. 6A and 6B. Thus, the second hybrid bonding structure component 40B is mounted. At this time, the terminal electrode 31a of the fourth semiconductor chip 30B is connected to the terminal electrode 21a of the first semiconductor chip 20A via the second connection bump 50B. At this time, a region other than the second connection bump 50B between the first hybrid bonding structure component 40A and the second hybrid bonding structure component 40B is a gap V.

Subsequently, as illustrated in FIG. 6B, when the second hybrid bonding structure component 40B is mounted, the curable second liquid material is injected into the gap V between the second hybrid bonding structure component 40B and the first hybrid bonding structure component 40A by a syringe or the like, as in the steps (g) and (h). The second liquid material injected in this manner is cured. The second liquid material is the same material as the first liquid material. Such a second liquid material protects the second connection bump 50B, while protecting the connection between the second hybrid bonding structure component 40B and the first hybrid bonding structure component 40A. As described above, the semiconductor device illustrated in FIG. 1 can be obtained.

### [Modification]

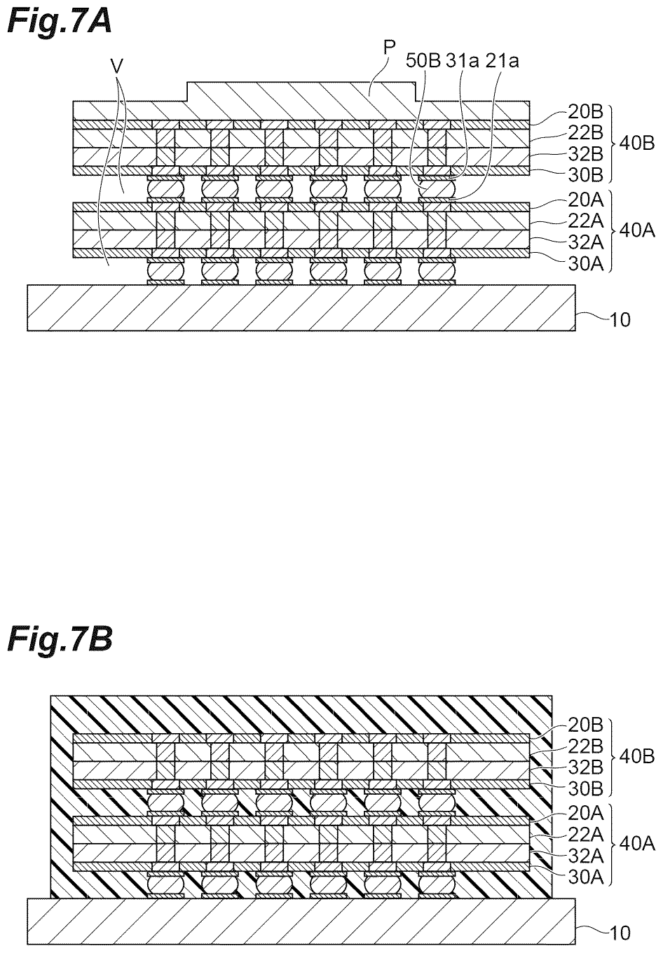

Next, a modification of the method for producing the semiconductor device of the present disclosure will be described with reference to FIGS. 7A and 7B. In the modification illustrated in FIGS. 7A and 7B, the plurality of gaps V are collectively filled using an encapsulating material that encapsulates the stacked semiconductor chips, instead of filling the gap V each time each hybrid bonding structure component is mounted.

Specifically, after the step (f) illustrated in FIG. 5A is completed, the first liquid material is not injected, and instead, the second hybrid bonding structure component 40B is picked up by the bonding tool P and the second hybrid bonding structure component 40B is placed on the first hybrid bonding structure component 40A and pressed while being heated. Thus, as illustrated in FIG. 7A, the second hybrid bonding structure component 40B is mounted. At this time, no resin or the like has been injected into any gap V.

Subsequently, a step of collectively encapsulating the plurality of stacked semiconductor chips is performed. By encapsulating the semiconductor chips with such an encapsulating material, warpage or the like of the semiconductor device is prevented. In the production method according to this modification, in the encapsulating step, the encapsulating material is injected into the gap V between the substrate 10 and the first hybrid bonding structure component 40A and the gap V between the first hybrid bonding structure component 40A and the second hybrid bonding structure component 40B, and then the encapsulating material is cured. By such a production method, the step of injecting the first liquid material and the step of injecting the second liquid material can be collectively performed.

Such an encapsulating material is also called a mold underfill (MUF), and for example, a liquid resin composition containing a liquid epoxy resin, a curing agent containing a liquid aromatic amine, rubber particles, and an inorganic filler can be used. The rubber particles may be, for example, acrylic rubber.

As described above, in the method for producing the semiconductor device according to the present embodiment, the hybrid bonding structure S is fabricated using the hybrid bonding technique that bonds together and connects the semiconductor chips (or the semiconductor wafers or the like) without using the connection bump, the connection bump is formed on the hybrid bonding structure S, and the hybrid bonding structure is diced to obtain the plurality of hybrid bonding structure components 40. Then, mounting is performed using such a first hybrid bonding structure component 40A having the connection bump, and the first liquid material is injected into the gap with another component on which the first hybrid bonding structure component is mounted, and the first liquid material is cured. According to such a production method, since the hybrid bonding technique is used to connect some of the semiconductor chips, the thickness and the height of the semiconductor device can be reduced as compared with the case where all the semiconductor chips are connected by the connection bumps. In addition, in the conventional production method, the production process is long because the semiconductor chips are stacked and connected by flip-chip connection at each stage; however, according to the above-described method for producing the semiconductor device, it is possible to collectively connect some of the semiconductor chips using the hybrid bonding technique, thus making it possible to shorten the production process and improve productivity.

The method for producing the semiconductor device according to the present embodiment further includes the steps of: mounting the second hybrid bonding structure component 40B on the first hybrid bonding structure component 40A; injecting the curable second liquid material into the gap V between the second hybrid bonding structure component 40B and the first hybrid bonding structure component 40A; and curing the second liquid material. According to the production method, it is possible to reduce the height of the semiconductor device even when the semiconductor chips are stacked in multiple stages. In addition, the production process of the semiconductor device can be shortened to improve productivity.

In the method for producing the semiconductor device according to the present embodiment, the step of injecting the first liquid material and the step of injecting the second liquid material may be separately performed. According to the production method, the injection of the first liquid material and the injection of the second liquid material can be performed more reliably, thus making it possible to easily fabricate a highly reliable semiconductor device.

The method for producing the semiconductor device according to the present embodiment may further include the step of encapsulating the first hybrid bonding structure component 40A and the second hybrid bonding structure component 40B, and the step of injecting the first liquid material and the step of injecting the second liquid material may be performed in this encapsulating step. According to the production method, the encapsulating material is used not only to encapsulate the first hybrid bonding structure component 40A and the second hybrid bonding structure component 40B, but also as an underfill material, and thus it is possible to collectively perform the encapsulating of the hybrid bonding structure components and the protection of the connection bumps. Therefore, according to the production method, the productivity of the semiconductor device can be further improved.

In the method for producing the semiconductor device according to the present embodiment, the other member is the substrate 10 having the wiring electrode 12 provided on the surface, and in the step of mounting the first hybrid bonding structure component 40A, the first hybrid bonding structure component 40A is mounted on the substrate 10 such that the first connection bump 50A of the first hybrid bonding structure component 40A is connected to the wiring electrode 12. According to the production method, it is possible to reduce the height of the semiconductor device in which the semiconductor chip is mounted on the substrate.

In the method for producing the semiconductor device according to the present embodiment, at least one of the first insulating layer 76 of the first semiconductor substrate 70 and the second insulating layer 86 of the second semiconductor substrate 80 may include an inorganic insulating material. According to the production method, it is possible to fabricate a semiconductor device having a finer configuration. In addition, since the joining between inorganic materials is easily strengthened, it is possible to increase the adhesive strength between the semiconductor chips, and further improve the connection reliability as the semiconductor device.

In the method for producing the semiconductor device according to the present embodiment, at least one of the first insulating layer 76 of the first semiconductor substrate 70 and the second insulating layer 86 of the second semiconductor substrate 80 may include an organic insulating material. According to the production method, the organic material, which is a relatively soft material, absorbs (incorporates) debris generated when the semiconductor substrate is diced into the semiconductor chip in the insulating layer portion made of the organic material, thus making it possible to reduce connection failure between the semiconductor chips joined by hybrid bonding.

In the method for producing the semiconductor device according to the present embodiment, the organic insulating material included in at least one of the first insulating layer 76 and the second insulating layer 86 may contain polyimide, a polyimide precursor, polyamideimide, benzocyclobutene (BCB), polybenzoxazole (PBO), or a PBO precursor. In this case, since these materials are liquid or soluble in a solvent, the first insulating layer and the like can be easily fabricated by, for example, spin coating, making it easier to form a thin film. In addition, since these materials are highly heat resistant, they can withstand high temperatures and the like when joining is performed by hybrid bonding, thus making it possible to perform joining between the semiconductor chips more reliably.

### Reference Signs List

1 Semiconductor device
10 Substrate (Another component)
12 Wiring electrode
20A First semiconductor chip
20B Third semiconductor chip
21a Terminal electrode
21b Through electrode
22A First insulating layer
22B Third insulating layer
24A First electrode
24B Third electrode
26A First semiconductor component
26B Third semiconductor component
30A Second semiconductor chip
30B Fourth semiconductor chip
31a Terminal electrode
31b Through electrode
32A Second insulating layer
32B Fourth insulating layer
34A Second electrode
34B Fourth electrode
36A Second semiconductor component
36B Fourth semiconductor component
40 Hybrid bonding structure component
40A First hybrid bonding structure component
40B Second hybrid bonding structure component
50 Connection bump
50A First connection bump
50B Second connection bump
55A First connector
55B Second connector
70 First semiconductor substrate
72 First substrate body
74 First electrode
76 First insulating layer
80 Second semiconductor substrate
82 Second substrate body
84 Second electrode
86 Second insulating layer
S Hybrid bonding structure
V Gap

1. A method for producing a semiconductor device comprising:
preparing a first semiconductor substrate including a first substrate body, a first insulating layer, and a plurality of first electrodes, the first substrate body including a plurality of first semiconductor elements, the first insulating layer and the plurality of first electrodes being provided on the first substrate body;
preparing a second semiconductor substrate including a second substrate body, a second insulating layer, and a plurality of second electrodes, the second substrate body including a plurality of second semiconductor elements, the second insulating layer and the plurality of second electrodes being provided on the second substrate body;
bonding the first insulating layer of the first semiconductor substrate and the second insulating layer of the second semiconductor substrate to each other and joining the plurality of first electrodes of the first semiconductor substrate to the plurality of second electrodes of the second semiconductor substrate to obtain a hybrid bonding structure;
forming a plurality of connection bumps on a surface of the second substrate body opposite to the second insulating layer;
dicing the hybrid bonding structure in which the plurality of connection bumps are formed to obtain a plurality of hybrid bonding structure components each including at least one first semiconductor element, at least one first electrode, at least one second semiconductor element, at least one second electrode, and at least one connection bump;
mounting a first hybrid bonding structure component among the plurality of hybrid bonding structure components on another member;
injecting a curable first liquid material into a gap between the first hybrid bonding structure component and the other member; and
curing the first liquid material.

2. The method for producing a semiconductor device according to claim 1, further comprising:
mounting a second hybrid bonding structure component among the plurality of hybrid bonding structure components on the first hybrid bonding structure component;
injecting a curable second liquid material into a gap between the second hybrid bonding structure component and the first hybrid bonding structure component; and
curing the second liquid material.

3. The method for producing a semiconductor device according to claim 2, wherein
the injecting of the first liquid material and the injecting of the second liquid material are separately performed.

4. The method for producing a semiconductor device according to claim 2, further comprising:
encapsulating the first hybrid bonding structure component and the second hybrid bonding structure component, wherein the injecting of the first liquid material and the injecting of the second liquid material are performed in the encapsulating.

5. The method for producing a semiconductor device according to claim 1, wherein
the other member is a substrate having a wiring electrode provided on a surface, and
in the mounting of the first hybrid bonding structure component, the first hybrid bonding structure component is mounted on the substrate such that the connection bump of the first hybrid bonding structure component is connected to the wiring electrode.

6. The method for producing a semiconductor device according to claim 1, wherein
at least one of the first insulating layer of the first semiconductor substrate and the second insulating layer of the second semiconductor substrate includes an inorganic insulating material.

7. The method for producing a semiconductor device according to claim 1, wherein
at least one of the first insulating layer of the first semiconductor substrate and the second insulating layer of the second semiconductor substrate includes an organic insulating material.

8. The method for producing a semiconductor device according to claim 7, wherein
the organic insulating material included in at least one of the first insulating layer and the second insulating layer contains polyimide, a polyimide precursor, polyamideimide, benzocyclobutene (BCB), polybenzoxazole (PBO), or a PBO precursor.

9. The method for producing a semiconductor device according to claim 1, wherein
the first liquid material is a liquid epoxy resin composition containing at least an epoxy resin and a curing agent.

10. A semiconductor device comprising:
a first hybrid bonding structure component including a first semiconductor component, a second semiconductor component, and a first connection bump, the first semiconductor component including a first semiconductor chip, and a first insulating layer and a first electrode that are provided on the first semiconductor chip, the second semiconductor component including a second semiconductor chip, and a second insulating layer and a second electrode that are provided on a first surface of the second semiconductor chip, the first connection bump being provided on a second surface of the second semiconductor chip and connected to an electrode of the second semiconductor chip, wherein the first insulating layer and the second insulating layer are bonded to each other, while the first electrode is joined to the second electrode;
another member on which the first hybrid bonding structure component is mounted; and
a cured object of a first liquid material injected between the first hybrid bonding structure component and the other member so as to cover the first connection bump, to be cured.

11. The semiconductor device according to claim 10, comprising:
a second hybrid bonding structure component mounted on the first hybrid bonding structure component, the second hybrid bonding structure component including a third semiconductor component, a fourth semiconductor component, and a second connection bump, the third semiconductor component including a third semiconductor chip, and a third insulating layer and a third electrode that are provided on the third semiconductor chip, the fourth semiconductor component including a fourth semiconductor chip, and a fourth insulating layer and a fourth electrode that are provided on a first surface of the fourth semiconductor chip, the second connection bump being provided on a second surface of the fourth semiconductor chip and connected to an electrode of the fourth semiconductor chip, wherein the third insulating layer and the fourth insulating layer are bonded to each other while the third electrode is joined to the fourth electrode; and
a cured object of a second liquid material injected between the second hybrid bonding structure component and the first hybrid bonding structure component so as to cover the second connection bump, to be cured.

12. The semiconductor device according to claim 10, wherein
the other member is a substrate having a wiring electrode, and
the first connection bump is connected to the wiring electrode.

13. The semiconductor device according to claim 10, wherein
at least one of the first insulating layer and the second insulating layer includes an inorganic insulating material.

14. The semiconductor device according to claim 1, wherein
at least one of the first insulating layer and the second insulating layer includes an organic insulating material.

15. The semiconductor device according to claim 10, wherein
a cured object of the first liquid material is a cured object of a liquid epoxy resin composition containing at least an epoxy resin and a curing agent.
